(19) United States
(12) Patent Application Publication
(10) Pub. No.: US 2025/0208963 A1
(43) Pub. Date: Jun. 26, 2025

(54) CONDITIONING MEMORY DEVICES FOR TESTING USING PEER-TO-PEER TRANSFERS

(71) Applicant: Micron Technology, Inc., Boise, ID (US)

(72) Inventors: Michael R. SPICA, Eagle, ID (US); Thomas T. TANGELDER, Boise, ID (US)

(21) Appl. No.: 18/953,714

(22) Filed: Nov. 20, 2024

Related U.S. Application Data
(60) Provisional application No. 63/612,736, filed on Dec. 20, 2023.

(51) Int. Cl. G06F 11/22; G06F 11/263; G06F 15/173

(52) U.S. Cl. CPC G06F 11/2294; G06F 11/263; G06F 15/17368

(57) ABSTRACT

In some implementations, a device may cause a single host device to load data to a first memory device of a plurality of memory devices configured in a fabric. The device may cause the first memory device to propagate the data to one or more second memory devices, of the plurality of memory devices, via one or more peer-to-peer transfer operations to replicate the data from the first memory device to the one or more second memory devices without involvement of the single host device.

### CROSS REFERENCE TO RELATED APPLICATION

This patent application claims priority to U.S. Provisional Patent Application No. 63/612,736, filed on Dec. 20, 2023, and entitled “CONDITIONING MEMORY DEVICES USING PEER-TO-PEER TRANSFERS.” The disclosure of the prior application is considered part of and is incorporated by reference into this patent application.

### TECHNICAL FIELD

The present disclosure generally relates to memory devices, memory device operations, and, for example, to conditioning memory devices using peer-to-peer transfers.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, an electronic device may write to, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), holographic RAM (HRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source. In some examples, a memory device may be associated with a compute express link (CXL). For example, the memory device may be a CXL compliant memory device and/or may include a CXL interface.

### BRIEF DESCRIPTION OF THE DRAWINGS

FIG. 1 is a diagram illustrating an example system.

FIG. 2 is a diagram of an example system.

FIG. 3 is a flowchart of an example method associated with conditioning memory devices using peer-to-peer transfers.

### DETAILED DESCRIPTION

A testing system (e.g., automatic test equipment (ATE)) may be employed to test memory devices for defects or other irregularities that may affect performances of the memory devices. In a testing scenario, data may be loaded onto the memory devices to simulate use conditions. Because the memory devices may be numerous, multiple host devices may be used to load data onto the memory devices. The use of multiple host devices in a testing system may increase the cost and the complexity (e.g., due to the need to coordinate the multiple host devices) of the testing system. Moreover, each host device may be directly connected to multiple memory devices, and the host device may load data onto the multiple memory devices in sequence. This sequential data loading is excessively time consuming, thereby reducing a total testing throughput of the testing system.

Some implementations described herein enable a single host device to efficiently load data onto multiple memory devices to condition the multiple memory devices (e.g., for testing). In some implementations, the host device may load data onto one of the memory devices, and the data may be propagated from that memory device to all remaining memory devices using peer-to-peer transfers between memory devices. In this way, numerous memory devices may be quickly and efficiently conditioned (e.g., for testing) using only a single host device. Moreover, by using a single host device, a cost and a complexity of a system may be significantly reduced.

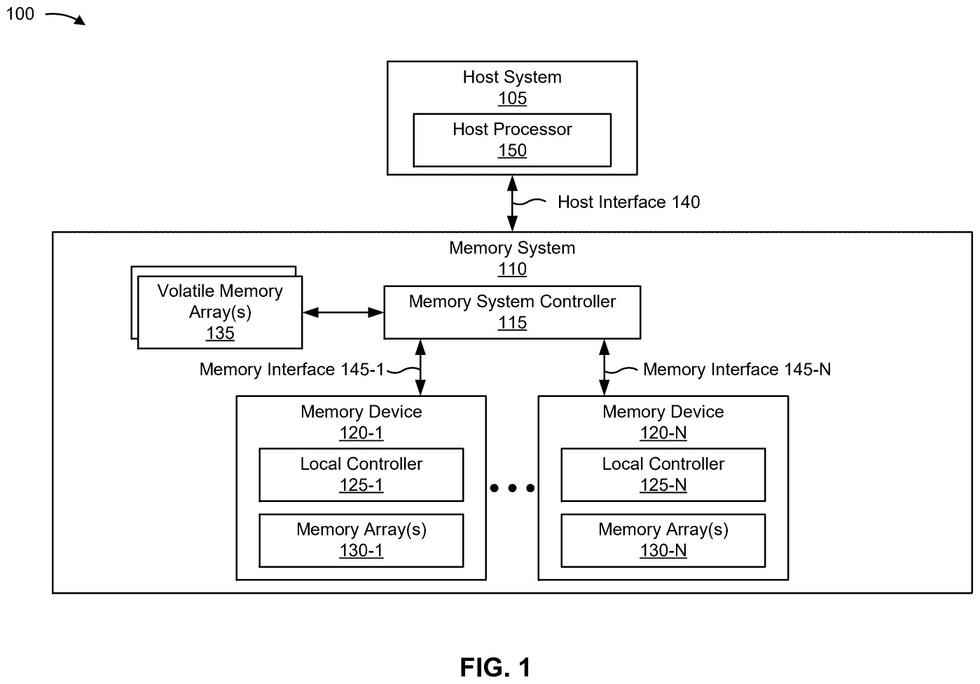

FIG. 1 is a diagram illustrating an example system 100. The system 100 may include one or more devices, apparatuses, and/or components for performing operations described herein. For example, the system 100 may include a host system 105 and a memory system 110. The memory system 110 may include a memory system controller 115 and one or more memory devices 120, shown as memory devices 120-1 through 120-N (where N≥1). A memory device may include a local controller 125 and one or more memory arrays 130. The host system 105 may communicate with the memory system 110 (e.g., the memory system controller 115 of the memory system 110) via a host interface 140. The memory system controller 115 and the memory devices 120 may communicate via respective memory interfaces 145, shown as memory interfaces 145-1 through 145-N (where N≥1).

The system 100 may be any electronic device configured to store data in memory. For example, the system 100 may be a computer, a mobile phone, a wired or wireless communication device, a network device, a server, a device in a data center, a device in a cloud computing environment, a vehicle (e.g., an automobile or an airplane), and/or an Internet of Things (IoT) device. The host system 105 may include a host processor 150. The host processor 150 may include one or more processors configured to execute instructions and store data in the memory system 110. For example, the host processor 150 may include a central processing unit (CPU), a graphics processing unit (GPU), a field-programmable gate array (FPGA), an application-specific integrated circuit (ASIC), and/or another type of processing component.

The memory system 110 may be any electronic device or apparatus configured to store data in memory. For example, the memory system 110 may be a hard drive, a solid-state drive (SSD), a flash memory system (e.g., a NAND flash memory system or a NOR flash memory system), a universal serial bus (USB) drive, a memory card (e.g., a secure digital (SD) card), a secondary storage device, a non-volatile memory express (NVMe) device, an embedded multimedia card (eMMC) device, a dual in-line memory module (DIMM), and/or a random-access memory (RAM) device, such as a dynamic RAM (DRAM) device or a static RAM (SRAM) device.

The memory system controller 115 may be any device configured to control operations of the memory system 110 and/or operations of the memory devices 120. For example, the memory system controller 115 may include control logic, a memory controller, a system controller, an ASIC, an FPGA, a processor, a microcontroller, and/or one or more processing components. In some implementations, the memory system controller 115 may communicate with the host system 105 and may instruct one or more memory devices 120 regarding memory operations to be performed by those one or more memory devices 120 based on one or more instructions from the host system 105. For example, the memory system controller 115 may provide instructions to a local controller 125 regarding memory operations to be performed by the local controller 125 in connection with a corresponding memory device 120.

A memory device 120 may include a local controller 125 and one or more memory arrays 130. In some implementations, a memory device 120 includes a single memory array 130. In some implementations, each memory device 120 of the memory system 110 may be implemented in a separate semiconductor package or on a separate die that includes a respective local controller 125 and a respective memory array 130 of that memory device 120. The memory system 110 may include multiple memory devices 120.

A local controller 125 may be any device configured to control memory operations of a memory device 120 within which the local controller 125 is included (e.g., and not to control memory operations of other memory devices 120). For example, the local controller 125 may include control logic, a memory controller, a system controller, an ASIC, an FPGA, a processor, a microcontroller, and/or one or more processing components. In some implementations, the local controller 125 may communicate with the memory system controller 115 and may control operations performed on a memory array 130 coupled with the local controller 125 based on one or more instructions from the memory system controller 115. As an example, the memory system controller 115 may be an SSD controller, and the local controller 125 may be a NAND controller.

A memory array 130 may include an array of memory cells configured to store data. For example, a memory array 130 may include a non-volatile memory array (e.g., a NAND memory array or a NOR memory array) or a volatile memory array (e.g., an SRAM array or a DRAM array). In some implementations, the memory system 110 may include one or more volatile memory arrays 135. A volatile memory array 135 may include an SRAM array and/or a DRAM array, among other examples. The one or more volatile memory arrays 135 may be included in the memory system controller 115, in one or more memory devices 120, and/or in both the memory system controller 115 and one or more memory devices 120. In some implementations, the memory system 110 may include both non-volatile memory capable of maintaining stored data after the memory system 110 is powered off and volatile memory (e.g., a volatile memory array 135) that requires power to maintain stored data and that loses stored data after the memory system 110 is powered off. For example, a volatile memory array 135 may cache data read from or to be written to non-volatile memory, and/or may cache instructions to be executed by a controller of the memory system 110.

The host interface 140 enables communication between the host system 105 (e.g., the host processor 150) and the memory system 110 (e.g., the memory system controller 115). The host interface 140 may include, for example, a Small Computer System Interface (SCSI), a Serial-Attached SCSI (SAS), a Serial Advanced Technology Attachment (SATA) interface, a Peripheral Component Interconnect Express (PCIe) interface, an NVMe interface, a USB interface, a Universal Flash Storage (UFS) interface, an eMMC interface, a double data rate (DDR) interface, and/or a DIMM interface.

In some examples, the memory device 120 may be a compute express link (CXL) compliant memory device 120. For example, the memory device 120 may include a PCIe/CXL interface (e.g., the host interface 150 may be associated with a PCIe/CXL interface). CXL is a high-speed CPU-to-device and CPU-to-memory interconnect designed to accelerate next-generation performance. CXL technology maintains memory coherency between the CPU memory space and memory on attached devices, which allows resource sharing for higher performance, reduced software stack complexity, and lower overall system cost. CXL is designed to be an industry open standard interface for high-speed communications. CXL technology is built on the PCIe infrastructure, leveraging PCIe physical and electrical interfaces to provide advanced protocol in areas such as input/output (I/O) protocol, memory protocol, and coherency interface.

The memory interface 145 enables communication between the memory system 110 and the memory device 120. The memory interface 145 may include a non-volatile memory interface (e.g., for communicating with non-volatile memory), such as a NAND interface or a NOR interface. Additionally, or alternatively, the memory interface 145 may include a volatile memory interface (e.g., for communicating with volatile memory), such as a DDR interface.

Although the example memory system 110 described above includes a memory system controller 115, in some implementations, the memory system 110 does not include a memory system controller 115. For example, an external controller (e.g., included in the host system 105) and/or one or more local controllers 125 included in one or more corresponding memory devices 120 may perform the operations described herein as being performed by the memory system controller 115. Furthermore, as used herein, a “controller” may refer to the memory system controller 115, a local controller 125, or an external controller. In some implementations, a set of operations described herein as being performed by a controller may be performed by a single controller. For example, the entire set of operations may be performed by a single memory system controller 115, a single local controller 125, or a single external controller. Alternatively, a set of operations described herein as being performed by a controller may be performed by more than one controller. For example, a first subset of the operations may be performed by the memory system controller 115 and a second subset of the operations may be performed by a local controller 125. Furthermore, the term “memory apparatus” may refer to the memory system 110 or a memory device 120, depending on the context.

A controller (e.g., the memory system controller 115, a local controller 125, or an external controller) may control operations performed on memory (e.g., a memory array 130), such as by executing one or more instructions. For example, the memory system 110 and/or a memory device 120 may store one or more instructions in memory as firmware, and the controller may execute those one or more instructions. Additionally, or alternatively, the controller may receive one or more instructions from the host system 105 and/or from the memory system controller 115, and may execute those one or more instructions. In some implementations, a non-transitory computer-readable medium (e.g., volatile memory and/or non-volatile memory) may store a set of instructions (e.g., one or more instructions or code) for execution by the controller. The controller may execute the set of instructions to perform one or more operations or methods described herein. In some implementations, execution of the set of instructions, by the controller, causes the controller, the memory system 110, and/or a memory device 120 to perform one or more operations or methods described herein. In some implementations, hardwired circuitry is used instead of or in combination with the one or more instructions to perform one or more operations or methods described herein. Additionally, or alternatively, the controller may be configured to perform one or more operations or methods described herein. An instruction is sometimes called a “command.”

For example, the controller (e.g., the memory system controller 115, a local controller 125, or an external controller) may transmit signals to and/or receive signals from memory (e.g., one or more memory arrays 130) based on the one or more instructions, such as to transfer data to (e.g., write or program), to transfer data from (e.g., read), to erase, and/or to refresh all or a portion of the memory (e.g., one or more memory cells, pages, sub-blocks, blocks, or planes of the memory). Additionally, or alternatively, the controller may be configured to control access to the memory and/or to provide a translation layer between the host system 105 and the memory (e.g., for mapping logical addresses to physical addresses of a memory array 130). In some implementations, the controller may translate a host interface command (e.g., a command received from the host system 105) into a memory interface command (e.g., a command for performing an operation on a memory array 130).

The number and arrangement of components shown in FIG. 1 are provided as an example. In practice, there may be additional components, fewer components, different components, or differently arranged components than those shown in FIG. 1. Furthermore, two or more components shown in FIG. 1 may be implemented within a single component, or a single component shown in FIG. 1 may be implemented as multiple, distributed components. Additionally, or alternatively, a set of components (e.g., one or more components) shown in FIG. 1 may perform one or more operations described as being performed by another set of components shown in FIG. 1.

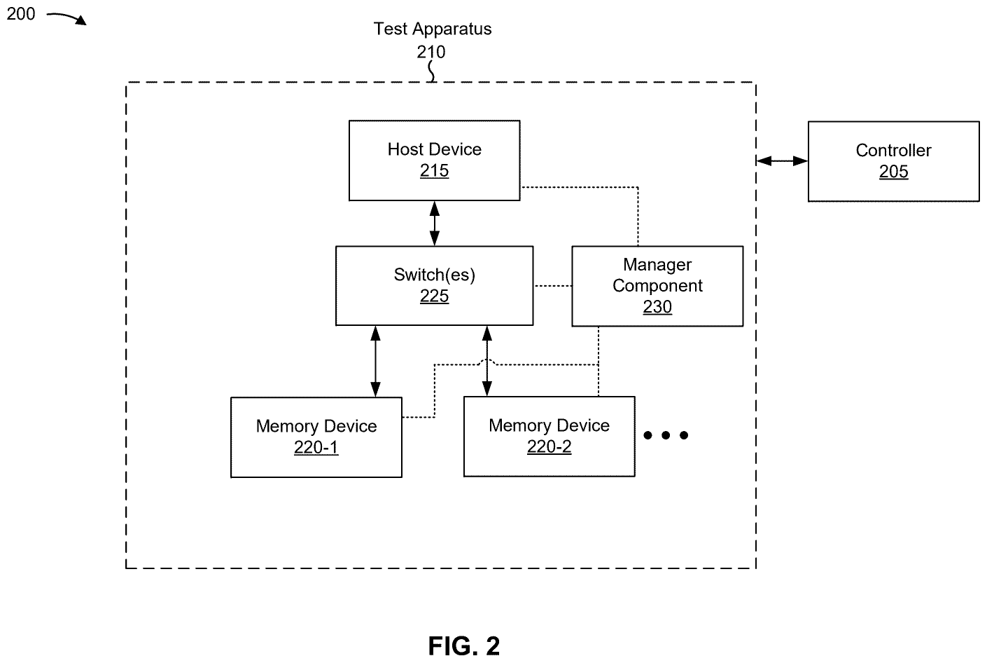

FIG. 2 is a diagram of an example system 200. As shown in FIG. 2, the system 200 (e.g., an ATE) may include a controller 205 and an apparatus 210. In some implementations, the apparatus 210 may correspond to the system 100 or one or more components of the system 100. The apparatus 210 may include a single host device 215 (e.g., only one host device 215) and a plurality of memory devices 220 (e.g., 10 or more memory devices 220, 50 or more memory devices 220, 100 or more memory devices 220, or the like). In some implementations, the host device 215 includes a CPU. The host device 215 may have an extended address range relative to an address range of a lower-cost host device that may be employed when multiple host devices are used for data loading. In some implementations, the host device 215 corresponds to the host system 105 and/or the host processor 150.

The memory devices 220 (e.g., the devices under test (DUT)) may include CXL devices (e.g., CXL compliant devices). In some implementations, the memory devices 220 may include Type 2 CXL devices. For example, the memory devices 220 may include accelerators (e.g., general-purpose accelerators), such as GPUs, ASICS, and/or FPGAs, which may include local memory (e.g., graphics DDR SDRAM or high bandwidth memory (HBM), among other examples). Additionally, or alternatively, the memory devices 220 may include Type 3 CXL devices. For example, the memory devices 220 may include memory expansion devices, such as volatile or persistent memory devices. As an example, a memory device 220 may include a memory controller (e.g., a CXL ASIC controller) and one or more memory packages coupled to the memory controller. In some implementations, the memory devices 220 may all have the same configuration (e.g., the memory devices 220 may be copies of each other). In some implementations, each memory device 220 may correspond to a memory system 110 or a memory device 120.

The host device 215 and the memory devices 220 may be arranged on one or more circuit boards of the apparatus 210. For example, a single circuit board may include the host device 215 and the memory devices 220. Alternatively, a first circuit board may include the host device 215 and one or more second circuit boards may include the memory devices 220. For example, the apparatus 210 may be configured as a rack system (e.g., a rack-mount appliance). The rack system allows many memory devices 220 to operate concurrently.

The memory devices 220 may be communicatively coupled with each other. For example, the memory devices 220 may be chained together. The memory devices 220 may be communicatively coupled by one or more switches 225 of the apparatus 210. In some implementations, the switch(es) 225 are CXL switches. The switch(es) 225 may include hardware bridges, such as PCIe bridges. Additionally, or alternatively, the switch(es) 225 may include network switches, such as Ethernet switches. The memory devices 220 may be communicatively coupled in various topologies. For example, the memory devices 220 may be communicatively coupled (e.g., by the switch(es) 225) in a ring topology, a star topology, a mesh topology, or a tree topology, among other examples. The host device 215 may be communicatively coupled to the memory devices 220 via the switch(es) 225 as well. “Communicative coupling” between two devices may refer to the two devices having a communication link that allows the exchange of information between the two devices.

In some implementations, the apparatus 210 (e.g., the host device 215, the memory devices 220, and/or the switch(es) 225) may be in a fabric configuration. For example, the apparatus 210 (e.g., the host device 215, the memory devices 220, and/or the switch(es) 225) may be in a configuration of a CXL fabric. The apparatus 210 may include a manager component 230. The manager component 230 may be configured to manage the fabric of the apparatus 210 (e.g., the manager component 230 may be a fabric manager). The manager component 230 may be a device or implemented in a device. For example, the manager component 230 may be implemented in hardware and/or software. The manager component 230 may reside in the host device 215 and/or one or more of the switches 225. Additionally, or alternatively, the manager component 230 may reside in a controller (e.g., a baseband management controller (BMC)), separate from the host device 215 and the switch(es) 225, and communicatively coupled to the host device 215, the switch(es) 225, and/or the memory devices 220.

As shown, the memory devices 220 may include a first memory device 220-1 and one or more second memory devices 220-2. The first memory device 220-1 may be configured to receive data from the host device 215. For example, the manager component 230 may cause the host device 215 to load data to the first memory device 220-1. The data may be for testing purposes, such as dummy data (e.g., data that is intended to mimic use conditions, but otherwise has no informational purpose). Alternatively, the data may be for common computing purposes, cluster operations, training retention, or the like.

The second memory device(s) 220-2 may be configured to receive the data from the first memory device 220-1 (e.g., via the switch(es) 225). For example, the manager component 230 may be configured to cause the first memory device 220-1 to propagate the data to the second memory device(s) 220-2. As an example, the host device 215 may load the data to the first memory device 220-1, and from the first memory device 220-1, the data may be propagated to the remaining second memory device(s) 220-2 (e.g., without intervention by the host device 215) using a fan-out propagation of the data (e.g., that is controlled by the manager component 230). For example, the data may be propagated from the first memory device 220-1 to the remaining second memory device(s) 220-2 using any propagation paths and any number of hops provided that the host device 215 is not involved in the propagation. As one example, the data may be propagated from the first memory device 220-1 to a first set of memory devices 220-2, from the first set of memory devices 220-2 to a second set of memory device 220-2, from the second set of memory devices 220-2 to a third set of memory devices 220-2, and so forth. In this way, with the single host device 215, data can be dictated to a single memory device 220, chained on the single memory device 220, and mimicked onto other memory devices 220.

The data may be propagated from the first memory device 220-1 to the second memory device(s) 220-2 via (e.g., the second memory device(s) 220-2 may receive the data via) one or more peer-to-peer transfer operations (e.g., via sideloading). For example, the manager component 230 may be configured to cause the peer-to-peer transfer operations. “Peer-to-peer transfer” may refer to a transfer from one memory device 220 to another memory device 220 without involvement of the host device 215. For example, a peer-to-peer transfer operation may allow one memory device 220 on a bus to move data to a neighboring memory device 220 on the bus (e.g., to thereby map data present on one memory device 220 to any number of cascaded memory devices 220). A peer-to-peer transfer operation may include a CXL memory operation (e.g., a CXL.mem transfer).

Propagation of the data from the first memory device 220-1 to the second memory device(s) 220-2 enables each of the memory devices 220 to operate with data transfers to simulate use conditions. Moreover, propagation of the data from the first memory device 220-1 to the second memory device(s) 220-2 may provide matching of the data loaded to the first memory device 220-1 and the second memory device(s) 220-2. In other words, the peer-to-peer transfer operation(s) may provide matching conditioning of the first memory device 220-1 and the second memory device(s) 220-2 (e.g., the peer-to-peer transfer operation(s) may attempt to load the same data to the memory devices 220). The peer-to-peer transfer operation(s) may condition the memory devices 220 for testing (e.g., testing for bit flipping or the like). For example, the matching conditioning of the memory devices 220 may facilitate testing of the memory devices 220 to be performed.

In some implementations, the peer-to-peer transfer operation(s) replicate the data from the first memory device 220-1 to the second memory device(s) 220-2 without involvement of the host device 215. The replication of the data may be useful for a manufacturing test of the first memory device 220-1 and the second memory device(s) 220-2. Furthermore, the replication of the data may be useful for common computing and/or cluster operations. For example, the replication of the data may facilitate the identical propagation of a distributed database across multiple nodes (e.g., for redundancy and evaluation), and/or activation of an update to the distributed database across all nodes. In some implementations, the first memory device 220-1 may be configured to perform processing in memory (PIM) to modify the data (e.g., via algorithmic manipulation) that is to be replicated from the first memory device 220-1 to the second memory device(s) 220-2 (e.g., the manager component 230 may cause the second memory device(s) 220-2 to receive the data, as modified by the first memory device 220-1, via the one or more peer-to-peer transfers). Accordingly, a copy of the original data may be preserved on the first memory device 220-1, modified data may be loaded to a second memory device 220-2, and so forth (e.g., to enable playback of the algorithms quickly for training retention).

In some implementations, the memory devices 220 may be configured to return stored data to the host device 215 via one or more additional peer-to-peer transfer operations. For example, the manager component 230 may cause the memory devices 220 to return the stored data to the host device 215 via the additional peer-to-peer transfer operation(s). As an example, the second memory device(s) 220-2 may return the stored data to the first memory device 220-1 (or to a different ingress memory device 220) and then to the host device 215 using a fan-in returning (e.g., a reverse propagation of the stored data inward to the host device 215) of the stored data (e.g., that is controlled by the manager component 230). The stored data may be returned using the same propagation paths through the memory devices 220 that was used to propagate out the data, or using different propagation paths through the memory devices 220 than the propagation paths used to propagate out the data. “Stored data” from a memory device 220 may refer to the resulting data stored by the memory device 220 after the memory device 220 has received the data. In most cases, the stored data may match the data. However, in some cases, the stored data may not match the data (e.g., due to bit flipping), thereby indicating device faultiness.

In some implementations, the controller 205 may be or may be implemented in the host device 215. Additionally, or alternatively, the host device 215 may be configured to perform one or more of the functions described herein as being performed by the controller 205. The controller 205 may be configured to perform one or more operations relating to testing the memory devices 220. In some implementations, an operation may include initiating testing of the memory devices 220. For example, the controller 205 may cause the host device 215 and/or the manager component 230 to load the original data to the first memory device 220-1.

In some implementations, an operation may relate to regulating an environment of the memory devices 220 (e.g., to produce an oven condition) for testing. For example, the environment may be adjusted into stressed conditions (e.g., by applying a voltage or a temperature to the memory devices 220). As an example, an operation may include a temperature control operation to control the environment of the memory devices 220 (e.g., by raising the temperature of the environment to provide a hot stress or lowering the temperature of the environment to provide a cold stress). In this way, the memory devices 220 may have a consistent activity factor and consistent data operations that mimic use conditions while a stress is applied to the memory devices 220.

In some implementations, an operation may include a bit flipping testing operation. The bit flipping testing operation can be performed concurrently with the temperature control operation or without the temperature control operation. In the bit flipping testing operation, the controller 205 may receive the stored data returned by memory devices 220. For example, the controller 205 may receive the stored data from the host device 215 and/or the manager component 230. In the bit flipping testing operation, the controller 205 may process the stored data to identify whether bit flipping has occurred in any of the memory devices 220. For example, processing the stored data may include comparing bits of the stored data to bits of the data originally propagated to the memory devices 220 to identify any differences between the stored data and the (original) data (e.g., where a difference can indicate bit flipping).

In some implementations, testing the memory devices 220 may include regular (e.g., systematic or repetitive) data transfers among the memory devices 220 (e.g., so that a stress acceleration can be observed). For example, the controller 205 may schedule and/or cause the regular data transfers.

In some implementations, one or more systems, devices, apparatuses, components, and/or controllers of FIG. 1 and/or FIG. 2 may be configured to cause a single host device to load data to a first memory device of a plurality of memory devices; and cause the first memory device to propagate the data to one or more second memory devices, of the plurality of memory devices, via one or more peer-to-peer transfer operations to replicate the data from the first memory device to the one or more second memory devices without involvement of the single host device.

As indicated above, FIG. 2 is provided as an example. Other examples may differ from what is described with regard to FIG. 2.

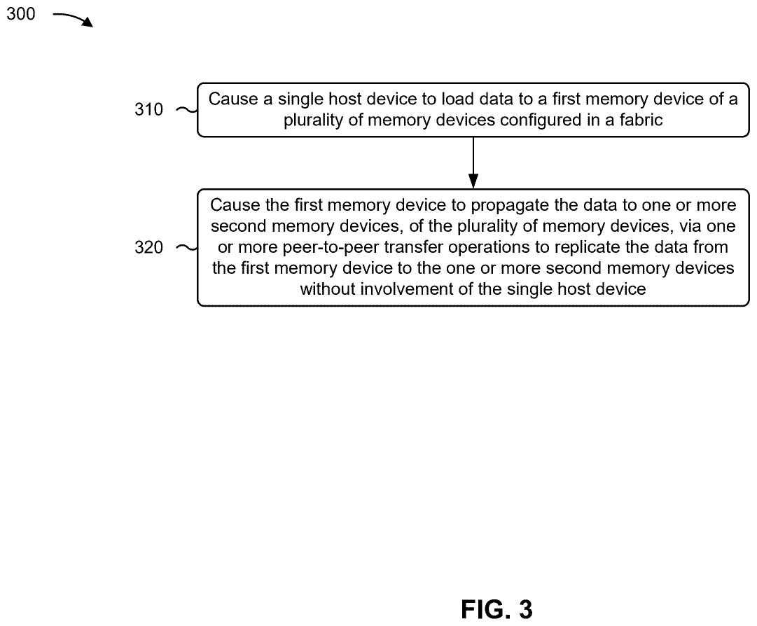

FIG. 3 is a flowchart of an example method 300 associated with conditioning memory devices using peer-to-peer transfers. In some implementations, a device (e.g., the apparatus 210, the switch(es) 225, the manager component 230, and/or the controller 205) may perform or may be configured to perform the method 300. In some implementations, another device or a group of devices separate from or including the device may perform or may be configured to perform the method 300. Additionally, or alternatively, one or more components of the device may perform or may be configured to perform the method 300. Thus, means for performing the method 300 may include the device and/or one or more components of the device. Additionally, or alternatively, a non-transitory computer-readable medium may store one or more instructions that, when executed by the device, cause the device to perform the method 300.

As shown in FIG. 3, the method 300 may include causing a single host device to load data to a first memory device of a plurality of memory devices configured in a fabric (block 310). As further shown in FIG. 3, the method 300 may include causing the first memory device to propagate the data to one or more second memory devices, of the plurality of memory devices, via one or more peer-to-peer transfer operations to replicate the data from the first memory device to the one or more second memory devices without involvement of the single host device (block 320).

The method 300 may include additional aspects, such as any single aspect or any combination of aspects described below and/or described in connection with one or more other methods or operations described elsewhere herein.

In a first aspect, causing the first memory device to propagate the data to the one or more second memory devices includes causing a fan-out propagation of the data.

In a second aspect, alone or in combination with the first aspect, the method 300 includes causing, by the device, the plurality of memory devices to return stored data to the single host device via one or more additional peer-to-peer transfer operations.

In a third aspect, alone or in combination with one or more of the first and second aspects, causing the plurality of memory devices to return the stored data to the single host device includes causing a fan-in returning of the stored data.

In a fourth aspect, alone or in combination with one or more of the first through third aspects, the plurality of memory devices are communicatively coupled in a ring topology, a star topology, a mesh topology, or a tree topology.

Although FIG. 3 shows example blocks of a method 300, in some implementations, the method 300 may include additional blocks, fewer blocks, different blocks, or differently arranged blocks than those depicted in FIG. 3. Additionally, or alternatively, two or more of the blocks of the method 300 may be performed in parallel. The method 300 is an example of one method that may be performed by one or more devices described herein. These one or more devices may perform or may be configured to perform one or more other methods based on operations described herein.

In some implementations, an apparatus includes a single host device and a plurality of memory devices configured in a fabric, including a first memory device configured to receive data from the single host device, and one or more second memory devices configured to receive the data from the first memory device via one or more peer-to-peer transfer operations that are caused via a manager component for the fabric, the one or more peer-to-peer transfer operations to replicate the data from the first memory device to the one or more second memory devices without involvement of the single host device.

In some implementations, a method includes causing, by a device, a single host device to load data to a first memory device of a plurality of memory devices configured in a fabric, and causing, by the device, the first memory device to propagate the data to one or more second memory devices, of the plurality of memory devices, via one or more peer-to-peer transfer operations to replicate the data from the first memory device to the one or more second memory devices without involvement of the single host device.

In some implementations, an apparatus includes a single host device, a plurality of memory devices configured in a fabric with the single host device, and a fabric manager for the fabric. In some implementations, the fabric manager is configured to cause a first memory device, of the plurality of memory devices, to receive data from the single host device, and cause one or more second memory devices, of the plurality of memory devices, to receive the data from the first memory device via one or more peer-to-peer transfer operations without involvement of the single host device.

The foregoing disclosure provides illustration and description but is not intended to be exhaustive or to limit the implementations to the precise forms disclosed. Modifications and variations may be made in light of the above disclosure or may be acquired from practice of the implementations described herein.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

When “a component” or “one or more components” (or another element, such as “a controller” or “one or more controllers”) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. An apparatus, comprising:
a single host device; and
a plurality of memory devices configured in a fabric, comprising:
a first memory device configured to receive data from the single host device; and
one or more second memory devices configured to receive the data from the first memory device via one or more peer-to-peer transfer operations that are caused via a manager component for the fabric,
the one or more peer-to-peer transfer operations to replicate the data from the first memory device to the one or more second memory devices without involvement of the single host device.

2. The apparatus of claim 1, wherein the one or more peer-to-peer transfer operations replicate the data from the first memory device to the one or more second memory devices to enable testing of the first memory device and the one or more second memory devices.

3. The apparatus of claim 1, wherein the first memory device is further configured to perform processing in memory to modify the data that is to be replicated from the first memory device to the one or more second memory devices.

4. The apparatus of claim 1, wherein the plurality of memory devices comprise a plurality of Compute Express Link (CXL) devices.

5. The apparatus of claim 1, wherein the plurality of memory devices comprise a plurality of accelerators.

6. The apparatus of claim 1, wherein the plurality of memory devices comprise a plurality of volatile or persistent memory devices.

7. The apparatus of claim 1, wherein the plurality of memory devices have a same configuration.

8. The apparatus of claim 1, wherein the fabric comprises one or more switches communicatively coupling the plurality of memory devices.

9. The apparatus of claim 1, wherein the one or more peer-to-peer transfer operations are one or more Compute Express Link (CXL) memory operations.

10. A method, comprising:
causing, by a device, a single host device to load data to a first memory device of a plurality of memory devices configured in a fabric; and
causing, by the device, the first memory device to propagate the data to one or more second memory devices, of the plurality of memory devices, via one or more peer-to-peer transfer operations to replicate the data from the first memory device to the one or more second memory devices without involvement of the single host device.

11. The method of claim 10, wherein causing the first memory device to propagate the data to the one or more second memory devices comprises causing a fan-out propagation of the data.

12. The method of claim 10, further comprising:
causing, by the device, the plurality of memory devices to return stored data to the single host device via one or more additional peer-to-peer transfer operations.

13. The method of claim 12, wherein causing the plurality of memory devices to return the stored data to the single host device comprises causing a fan-in returning of the stored data.

14. The method of claim 10, wherein the plurality of memory devices are communicatively coupled in a ring topology, a star topology, a mesh topology, or a tree topology.

15. An apparatus, comprising:
a single host device;
a plurality of memory devices configured in a fabric with the single host device; and
a fabric manager, for the fabric, configured to:
cause a first memory device, of the plurality of memory devices, to receive data from the single host device; and
cause one or more second memory devices, of the plurality of memory devices, to receive the data from the first memory device via one or more peer-to-peer transfer operations without involvement of the single host device.

16. The apparatus of claim 15, wherein the fabric manager is configured to cause the one or more second memory devices to receive the data from the first memory device via the one or more peer-to-peer transfers to replicate the data from the first memory device to the one or more second memory devices.

17. The apparatus of claim 15, wherein the fabric manager is configured to cause the one or more second memory devices to receive the data, as modified by the first memory device, via the one or more peer-to-peer transfers.

18. The apparatus of claim 15, wherein the fabric manager is further configured to cause the plurality of memory devices to return stored data to the single host device via one or more additional peer-to-peer transfer operations.

19. The apparatus of claim 15, further comprising:
one or more switches communicatively coupling the plurality of memory devices.

20. The apparatus of claim 19, wherein the fabric manager is implemented in the one or more switches.
